(19) United States
(12) Patent Application Publication
(10) Pub. No.: US 2025/0316997 A1
(43) Pub. Date: Oct. 9, 2025

(54) APPARATUS FOR CHARGING OR DISCHARGING, BATTERY CHARGING OR DISCHARGING SYSTEM INCLUDING THE SAME, AND CONTROLLING METHOD THEREOF

(71) Applicant: SK On Co., Ltd., Seoul (KR)

(72) Inventors: Chang Mook HWANG, Daejeon (KR); Chul Ho KANG, Daejeon (KR); Gyeong Min RYU, Daejeon (KR); Sin Young MOON, Daejeon (KR); Ji Hyeon LEE, Daejeon (KR)

(21) Appl. No.: 18/986,015

(22) Filed: Dec. 18, 2024

(30) Foreign Application Priority Data
Dec. 18, 2023 (KR) 10-2023-0184663

(51) Int. Cl. H02J 7/00; H05K 7/20

(52) U.S. Cl. CPC H02J 7/0045; H02J 7/0047; H02J 7/007192; H05K 7/20209

(57) ABSTRACT

The disclosure relates to an apparatus for charging or discharging including a case, a charging or discharging module unit and an air treatment unit provided inside the case, an equipment temperature sensor located in the case and sensing an equipment temperature, a module hole formed by communicating with the outside, and a controller charging or discharging, where the controller is configured to discharge at least a portion of the air discharged from the air treatment unit to the outside of the case through the module hole based on usage current of the charging or discharging module unit and the equipment temperature, a battery charging or discharging system including the same, and a control method thereof.

### CROSS-REFERENCE TO RELATED PATENT APPLICATION

This application claims priority under 35 U.S.C. § 119(a) to Korean patent application number 10-2023-0184663, filed on Dec. 18, 2023, in the Korean Intellectual Property Office, the disclosure of which is incorporated by reference herein in its entirety.

### BACKGROUND OF THE INVENTION

### 1. Technical Field

The disclosure relate to an apparatus for charging or discharging used in one of assembly processes of a secondary battery or a battery cell, a battery charging or discharging system including the apparatus for charging or discharging, and a control method of the apparatus for charging or discharging or the battery charging or discharging system. More specifically, embodiments of the disclosure relate to an apparatus for charging or discharging or a control method of a battery charging or discharging system for air-conditioning a space in which the apparatus for charging or discharging is located by using the apparatus for charging or discharging.

### 2. Description of the Related Art

A production process of secondary batteries may be broadly classified into an electrode process, an assembly (packaging) process, a charging or discharging process (or activation), and a degassing process. In particular, the charging or discharging process refers to a process of providing electrical characteristics to a secondary battery and testing discharge capacity by repeatedly charging or discharging the secondary battery initially discharged multiple times to form a solid electrolyte interphase (SEI) layer on an anode.

In general, the apparatus for charging or discharging repeatedly charges and discharges a battery cells, so heat generation is inevitably involved in this process. Therefore, it is required to keep the temperature of the apparatus for charging or discharging and a space in which the apparatus for charging or discharging is located below a predetermined temperature.

### SUMMARY

According to one aspect of the disclosure, an object is to efficiently air-condition not only an apparatus for charging or discharging but also an apparatus installation space in which the apparatus for charging or discharging is located by utilizing the apparatus for charging or discharging.

According to another aspect of the disclosure, an object is to use a transfer member organically.

According to another aspect of the disclosure, an object is to enable separate discharge of the transfer member when a defect occurs.

According to another aspect of the disclosure, an object is to improve production efficiency of a battery manufacturing system and to control the battery manufacturing system stably.

A battery cell manufactured using an apparatus for charging or discharging or a battery charging or discharging system including the same according to the disclosure may be widely applied in green technology fields such as electric vehicles, battery charging stations, energy storage systems (ESS), and other battery-based photovoltaics and wind power. In addition, a battery cell manufactured using an apparatus for charging or discharging or a battery charging or discharging system including the same according to the disclosure may be used for eco-friendly mobility, including electric vehicles and hybrid vehicles, to prevent climate change by suppressing air pollution and greenhouse gas emissions.

An apparatus for charging or discharging according to the disclosure includes: a case including a receiving port in a front surface; a receiving chamber located inside the case and receiving at least one battery cell through the receiving port; a charging or discharging module unit configured to charge and discharge the at least one battery cell accommodated in the receiving chamber inside the case; an air treatment unit provided inside the case and configured to discharge air toward the charging or discharging module unit to cool the charging or discharging module unit; an equipment temperature sensor located in the case and sensing an equipment temperature, which is a temperature outside the case; a module hole formed by penetrating the case and communicating with an outside; a module cover which opens or closes the module hole; and a controller configured to control the charging or discharging module unit, the air treatment unit, and the equipment temperature sensor.

The controller may be configured to open the module cover to discharge at least a portion of the air discharged from the air treatment unit to the outside of the case through the module hole based on usage current of the charging or discharging module unit and the equipment temperature.

The controller may be configured to discharge at least a portion of the air discharged from the air treatment unit to the outside of the case through the module hole, when the usage current of the charging or discharging module unit is less than a preset allowable current and the equipment temperature reaches a preset allowable equipment temperature.

In addition, the controller may be configured to maintain the module hole closed through the module cover, when the usage current of the charging or discharging module unit is greater than or equal to the allowable current.

In addition, the controller may be configured to maintain the module hole closed through the module cover, when the usage current of the charging or discharging module unit is less than the allowable current and the equipment temperature is less than the preset allowable equipment temperature.

The controller may be configured to discharge at least a portion of the air discharged from the air treatment unit to the outside of the case through the module hole, when the usage current of the charging or discharging module unit is less than the preset allowable current, and a time period during which the equipment temperature has reached the preset allowable equipment temperature and is continuously maintained above the allowable equipment temperature reaches a preset allowable time.

In addition, the controller may be configured to maintain the module hole closed through the module cover, when the usage current of the charging or discharging module unit is greater than or equal to the allowable current.

The controller may be configured to maintain the module hole closed through the module cover, when the usage current of the charging or discharging module unit is less than the allowable current and the equipment temperature is less than the allowable equipment temperature.

The controller may be configured to maintain the module hole closed through the module cover, when the usage current of the charging or discharging module unit is less than the allowable current and a time period during which the equipment temperature is continuously maintained above the allowable equipment temperature after reaching the allowable equipment temperature is shorter than the allowable time.

According to another aspect, a method of controlling a battery charging or discharging system, which includes a plurality of apparatuses for charging or discharging each including a case including a receiving port in a front surface; a receiving chamber located inside the case and receiving at least one battery cell through the receiving port; a charging or discharging module unit configured to charge and discharge the at least one battery cell accommodated in the receiving chamber inside the case; and an air treatment unit which is provided inside the case and configured to discharge air toward the charging or discharging module unit to cool the charging or discharging module unit; and a zone temperature sensor measuring a zone temperature which is a temperature of a zone in which the plurality of apparatuses for charging or discharging are installed, includes measuring an equipment temperature of each of the plurality of apparatuses for charging or discharging through an equipment temperature sensor which is provided in the case of the apparatus for charging or discharging and measures the equipment temperature of the apparatus for charging or discharging; selecting a cautionary apparatus for charging or discharging requiring temperature control among the plurality of apparatuses for charging or discharging based on the equipment temperature of each of the plurality of apparatuses for charging or discharging; measuring the zone temperature through the zone temperature sensor; and selecting an air conditioning range and starting an air conditioning mode to discharge at least a portion of the air discharged from respective air treatment units of at least one or more apparatuses for charging or discharging among the plurality of apparatuses for charging or discharging to an outside based on the zone temperature, the equipment temperature of the cautionary apparatus for charging or discharging, and usage current of respective charging or discharging module units of the plurality of apparatuses for charging or discharging.

In addition, the selecting of the cautionary apparatus for charging or discharging requiring the temperature control among the plurality of apparatuses for charging or discharging based on the equipment temperature of each of the plurality of apparatuses for charging or discharging may include determining whether the equipment temperature of each of the plurality of apparatuses for charging or discharging is higher than or equal to a preset allowable equipment temperature; and determining whether a time period during which the equipment temperature has reached the allowable equipment temperature and is continuously maintained above the allowable equipment temperature reaches a preset allowable time, and, among the plurality of apparatuses for charging or discharging, an apparatus for charging or discharging which has the equipment temperature higher than or equal to the allowable equipment temperature and reaches the allowable time may be selected as the cautionary apparatus for charging or discharging.

In the method of controlling the battery charging or discharging system according to the disclosure, among the plurality of apparatuses for charging or discharging, an apparatus for charging or discharging which has the equipment temperature is below the allowable equipment temperature or is shorter than the allowable time may measure the equipment temperature through the equipment temperature sensor.

The selecting of the air conditioning range and starting of the air conditioning mode may include starting the air conditioning mode in an apparatus for charging or discharging capable of air conditioning in which the usage current of the charging or discharging module unit is less than a preset allowable current among the plurality of apparatuses for charging or discharging when the zone temperature is higher than or equal to the equipment temperature of the cautionary apparatus for charging or discharging.

The selecting of the air conditioning range and starting of the air conditioning mode may include starting the air conditioning mode in an apparatus for charging or discharging capable of air conditioning in which the usage current of the charging or discharging module unit is less than the allowable current among apparatuses for charging or discharging located in a predetermined neighborhood area of the cautionary apparatus for charging or discharging when the zone temperature is lower than the equipment temperature of the cautionary apparatus for charging or discharging.

The selecting of the air conditioning range and starting of the air conditioning mode may include starting the air conditioning mode in an apparatus for charging or discharging capable of air conditioning in which the usage current of the charging or discharging module is less than a preset allowable current among the plurality of apparatuses for charging or discharging when the zone temperature is higher than or equal to a preset allowable zone temperature.

The selecting of the air conditioning range and starting of the air conditioning mode may include starting the air conditioning mode in an apparatus for charging or discharging capable of air conditioning in which the usage current of the charging or discharging module unit is lower than the allowable current among apparatuses for charging or discharging located in the neighborhood area of the cautionary apparatus for charging or discharging, when the zone temperature is lower than an allowable zone temperature.

The selecting of the cautionary apparatus for charging or discharging requiring the temperature control among the plurality of apparatuses for charging or discharging based on the equipment temperature of each of the plurality of apparatuses for charging or discharging may include prior to determining whether the equipment temperature of each of the plurality of apparatuses for charging or discharging is higher than or equal to the preset allowable equipment temperature, determining whether the equipment temperature reaches a preset equipment monitoring temperature; and notifying a user of an apparatus for charging or discharging which reaches the equipment monitoring temperature among the plurality of apparatuses for charging or discharging.

According to an embodiment of the disclosure, it is possible to efficiently utilize a space in which an apparatus for charging or discharging is located.

According to another embodiment of the disclosure, it is possible to improve transfer efficiency by organically utilizing a transfer member in a charging or discharging process.

According to another embodiment of the disclosure, it is possible to discharge the transfer member separately when a defect occurs during the charging or discharging process.

According to another embodiment of the disclosure, it is possible to increase the production efficiency of a battery manufacturing system and to stably control the battery manufacturing system.

### BRIEF DESCRIPTION OF THE DRAWINGS

FIG. 1 shows an example of an apparatus for charging or discharging according to the disclosure.

FIG. 2A is an example of a side view of an apparatus for charging or discharging according to the disclosure. FIG. 2B shows an example in which a modular hole is open.

FIG. 3 shows another example of an apparatus for charging or discharging according to the disclosure.

FIG. 4 shows an example in which a charging or discharging module unit is provided along a height direction of a case.

FIG. 5 shows an example of a battery charging or discharging system according to the disclosure.

FIG. 6 is a flowchart illustrating an example of a control method of an apparatus for charging or discharging according to the disclosure.

FIG. 7 is a flowchart illustrating an example of a control method of a battery charging or discharging system according to the disclosure.

### DETAILED DESCRIPTION

Hereinafter, preferred embodiments of the disclosure will be described in detail with reference to the accompanying drawings. A configuration of an apparatus or a control method described below is merely for explaining embodiments of the disclosure and is not intended to limit the scope of the disclosure, and the same reference numerals used throughout the present specification represent the same components.

Specific terms used in the present specification are merely for convenience of explanation and are not intended to limit the illustrated embodiments.

For example, expressions such as “identical” and “the same” not only indicate a strictly identical state, but also indicate a state in which there is a tolerance or a difference of the degree to which the same function is obtained.

For example, expressions indicating relative or absolute arrangements such as “in a direction”, “along a direction”, “parallel”, “perpendicular”, “centered”, “concentric”, or “coaxial” not only indicate the exact arrangements, but also indicate a state of relative displacement with tolerance or an angle or distance which provides the same function.

To describe the disclosure, the following is explained based on a spatial orthogonal coordinate system with an X-axis, a Y-axis, and a Z-axis being orthogonal to each other. Unless otherwise specified, a Z direction refers to a height direction, and an X direction (or a first direction) refers to any one of directions perpendicular to the height direction. Further, a Y direction (or a second direction) refers to a direction perpendicular to the Z direction and the X direction.

However, the X, Y, and Z directions mentioned below are provided for the purpose of explanation so that the disclosure can be clearly understood, and it is to be understood that each direction may be defined differently depending on where the reference is placed.

The use of terms such as ‘first’, ‘second’, and ‘third’ before components mentioned below is only intended to avoid confusion regarding the components they refer to, and has nothing to do with the order, importance, or main-subordinate relationship between the components. For example, an invention which includes only a second component without a first component may be implemented.

As used herein, singular expressions include plural expressions unless the context clearly indicates otherwise.

A battery cell described in the present specification refers to a lithium secondary battery, specifically, a lithium ion battery, which can be used by charging or discharging electric energy. The battery cell may be classified into pouch type, square type, and cylindrical type depending on the shape of the case, but an apparatus for charging or discharging according to the disclosure may be applied to any type of battery cell.

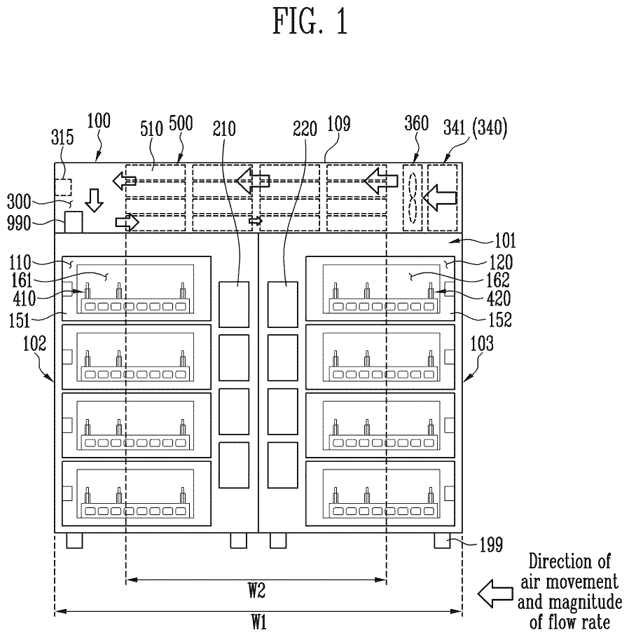

FIG. 1 shows an example of an apparatus for charging and discharge 1000 according to the disclosure.

Referring to FIG. 1, the apparatus for charging or discharging 1000 according to the disclosure may include a case 100 including receiving ports 110 and 120 in a front surface, receiving chambers 161 and 162 located inside the case 100 and receiving at least one battery cell (not shown) through the receiving ports 110 and 120, a charging or discharging module unit 500 for charging or discharging the at least one battery cell accommodated in the receiving chambers 161 and 162 inside the case 100, an air treatment unit 340 provided inside the case 100 and discharging air toward the charging or discharging module unit 500 to cool the charging or discharging module unit 500, an equipment temperature sensor 990 located in the case 100 and sensing an equipment temperature, which is a temperature outside the case 100, a module hole 325 formed by penetrating the case 100 and communicating with the outside, a module cover 321 which opens or closes the module hole 325, and a controller 600 which controls the charging or discharging module unit 500, the air treatment unit 340, and the equipment temperature sensor 990.

The case 100 may be provided to form an outer shape of the apparatus for charging or discharging 1000 and protect items accommodated inside. The case may roughly have a hexahedral shape. For this purpose, the case 100 may include a case front surface 101 forming the front surface of the case, a case first side surface 102 and a case second side surface 103 forming both side surfaces of the case 100 along a width direction of the case 100, and a case upper surface 109 forming an upper surface of the case 100.

The case 100 may include the receiving ports 110 and 120 in the case front surface 101. The receiving ports 110 and 120 may include a first port 110 and a second port 120.

The first port 110 and the second port 120 may be arranged side by side along the width direction of the case 100. In other words, along the width direction of the case 100, the second port 120 may be positioned apart from one side of the first port 110.

The case 100 includes the receiving chambers 161 and 162 to accommodate the battery cell inside through the receiving ports 110 and 120. In addition, the case 100 may further include receiving doors 151 and 152 which are rotatably coupled to the receiving chambers 161 and 162 to open and close the receiving ports 110 and 120.

For example, a first chamber 161 and a second chamber 162 may accommodate one or more battery cells (not known) through the first port 110 and the second port 120, respectively. Further, the receiving doors 151 and 152 may include a first door 151 and a second door 152 which are movably coupled to the case 100 to open and close the first port 110 and the second port 120, respectively.

Similarly to the receiving ports 110 and 120 being positioned at the same height based on a height direction of the case 100 and arranged in the width direction of the case 100, the receiving doors 151 and 152 may also be positioned at the same height based on the height direction of the case 100.

In other words, the first chamber 161 and the second chamber 162 may be located at the same height to position the first chamber 161 and the second chamber 162 symmetrically with respect to an imaginary vertical line parallel to the height direction of the case 100. This is to simplify wire connection between the charging or discharging module unit 500 and the first chamber 161, and between the charging or discharging module unit 500 and the second chamber 162, which will be described later.

The first chamber 161 and the second chamber 162 may accommodate a plurality of battery cells inside through the first port 110 and the second port 120, respectively. The first chamber 161 and the second chamber 162 may set a temperature and/or humidity to a preset chamber temperature and/or a preset chamber humidity and maintain the same. This is to charge and discharge the battery cells accommodated for a preset charge and discharge time in an environment where the chamber temperature and/or chamber humidity are maintained.

The chamber temperature, the chamber humidity, and the charge and discharge time may be different for each of the receiving chambers 161 and 162.

The apparatus for charging or discharging 1000 may include a first jig 410 which is provided so as to be inserted and withdrawn into the first chamber 161, which places the battery cell accommodated in the first chamber 161, and which is electrically connected to the charging or discharging module unit 500 to be described later and a second jig 420 which is provided so as to be inserted and withdrawn into the second chamber 162, which places the battery cell accommodated in the second chamber 162, and which is electrically connected to the charging or discharging module unit 500 to be described later.

Here, the battery cells may have different shapes. For example, if one of the battery cells is a pouch-type battery cell, the other of the battery cells may be a square-type battery cell.

The apparatus for charging or discharging 1000 may further include a support 199 to support the case 100 on the ground. The support 199 may be a kind of leg which supports the case 100 by separating the case 100 from the ground. This is to align the horizontal and vertical of the case 100.

The apparatus for charging or discharging 1000 includes a module chamber 300 which is a space separate from the first chamber 161 and the second chamber 162 inside the case 100.

The module chamber 300 may be a spatially separated space within the case 100 and may not have any special partitions or bulkheads. On the other hand, the module chamber 300 may be a space clearly separated by a partition or bulkhead.

The apparatus for charging or discharging 1000 includes the charging or discharging module unit 500 to charge and discharge the battery cell accommodated in the receiving chambers 161 and 162 inside the case 100. More specifically, the module chamber 300 may accommodate the battery cell accommodated in each of the first chamber 161 and the second chamber 162 and the charging or discharging module unit 500 for charging or discharging the battery cell.

As shown in FIG. 1, a plurality of the first chambers 161 and a plurality of the second chambers 162 may be provided, and the plurality of first chambers 161 and the plurality of second chambers 162 may be paired one by one and arranged along the height direction of the case 100.

The apparatus for charging or discharging 1000 may include a first input/output unit 210 detecting information such as the temperature and humidity of the first chamber 161, a charge and discharge state of the battery cell, and a user's input, and a second input/output unit 220 detecting information such as the temperature and humidity of the second chamber 162, a charge and discharge state of the battery cell, and the user input, which are located on the case front surface 101.

The first chamber 161 and the second chamber 162, the first door 151 and the second door 152, the first port 110 and the second port 120, and the first input/output unit 210 and the second input/output unit 220 may be positioned symmetrically with respect to an imaginary vertical line extending in the height direction of the case 100.

In other words, an imaginary vertical line passing through the halfway point of the length (W1) between the case first side surface 102 and the case second side surface 103 may coincide with an imaginary vertical line passing through the halfway point of the length (W2) of the charging or discharging module unit 500. Through this symmetrical arrangement, the disclosure may simplify arrangement of busbars or wires which electrically connect the charging or discharging module unit 500 and the first jig 410 and the second jig 420, respectively.

Due to heat generation during operation of the charging or discharging module unit 500, the temperature of the module chamber or the temperature inside the case may rise. To cool this and maintain the temperature of the module chamber or the temperature inside the case at a preset management temperature, the apparatus for charging or discharging 1000 includes the air treatment unit 340 which is provided inside the case 100 and discharges air toward the charging or discharging module unit 500 to cool the charging or discharging module unit 500.

In other words, the air treatment unit 340 may discharge air of a temperature lower than the equipment temperature, which is the temperature outside the case 100, to the charging or discharging module unit 500 to cool the charging or discharging module unit 500. To this end, to force the air past the air treatment unit 340 toward the charging or discharging module unit 500, the apparatus for charging or discharging 1000 may further include a module fan 360.

Thus, in view of airflow, it would be desirable for the module fan 360 to be located before passing through the charging or discharging module unit 500.

A temperature outside of the apparatus for charging or discharging 1000 may also affect the operation of the apparatus for charging or discharging 1000. To this end, a separate air conditioning device may be provided to lower the temperature outside the apparatus for charging or discharging 1000 in general, but the disclosure may use the air treatment unit 340 provided in the apparatus for charging or discharging 1000 to discharge air of a temperature lower than the equipment temperature to the outside of the apparatus for charging or discharging 1000. This may be called an air-conditioning mode.

To this end, the apparatus for charging or discharging 1000 includes the module hole 325 which penetrates the case 100 and fluidly communicates with the outside

The module hole 325 may serve as a passage to discharge at least a part of the air past the charging or discharging module unit 500 to the outside. Therefore, for example, the module fan 360 and the module hole 325 may be located in opposite directions with the charging or discharging module unit 500 interposed between the module fan 360 and the module hole 325.

For example, referring to FIG. 1, the module hole 325 may be located between the case first side surface 102 and the charging or discharging module unit 500, and the module fan 360 may be located between the case second side surface 103 and the charging or discharging module unit 500.

In addition, the apparatus for charging or discharging 1000 may further include the equipment temperature sensor 990 for sensing the outside temperature.

The outside temperature may refer to a temperature of a location where the apparatus for charging or discharging 1000 is located, in other words, the temperature outside the case 100. Referring to FIG. 1, the equipment temperature sensor 990 may be provided on the case front surface 101, but this is merely an example, and it may be located elsewhere.

While the receiving chambers 161 and 162 are arranged symmetrically left and right referring to FIG. 1, this is merely an example, and the receiving chambers 161 and 162 may be arranged in a single line along the height direction of the case 100.

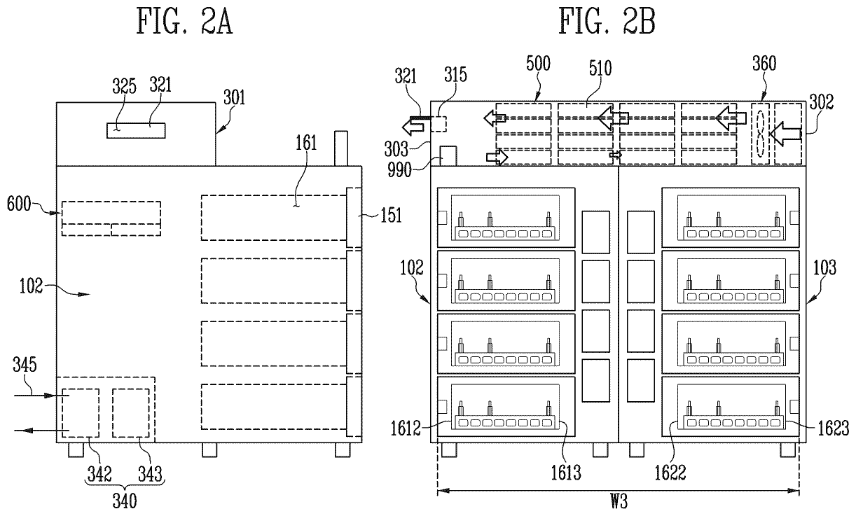

FIG. 2A is an example of a side view of the apparatus for charging or discharging 1000 according to the disclosure. FIG. 2B is an example in which the module hole 325 is open.

Referring to FIG. 2A, the module chamber 300 (see FIG. 1) in which the charging or discharging module unit 500 is located may be located at the rear of the first chamber 161 and the second chamber 162. In other words, the module chamber 300 may be located closer to a rear surface (not shown) of the case 100 than to the case front surface 101 (see FIG. 1). This is to prevent the apparatus for charging or discharging 1000 from falling forward, taking into account the weight of the charging or discharging module unit 500.

The charging or discharging module unit 500 may be located in an upper portion of the case 100 inside the case 100. However, alternatively, the charging or discharging module unit 500 may be formed on the outside of the case 100 as a separate chamber.

Unless otherwise specified, the present specification describes based on the module chamber 300 being located inside the case 100. Therefore, referring to FIG. 2A and FIG. 2B, a portion of the case first side surface 102 based on the width direction of the case 100 may form a module first side surface 302 which is one side surface of the module chamber 300. Similarly, a portion of the case second side surface 103 may form a module second side surface 303 which is the other side surface of the module chamber 300.

In other words, at least a portion of the case first side 102 may be formed by the module first side surface 302, and at least a portion of the case second side surface 103 may be formed by the module second side surface 303.

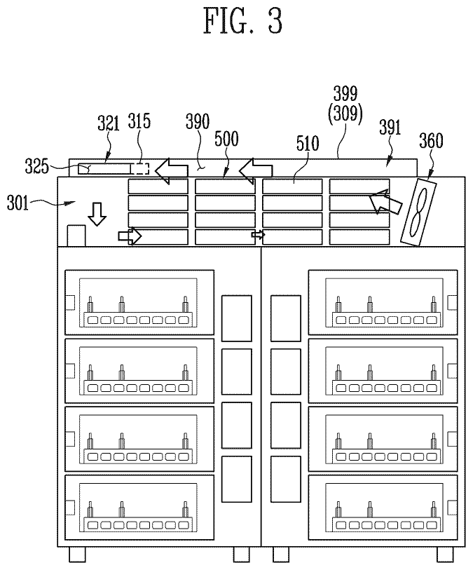

Further, referring to FIG. 2B, a module upper surface 309 forming an upper surface of the module chamber 300 may form at least a portion of the case upper surface 109. Similarly, a module front surface 301 (see FIG. 3), which forms a front surface of the module chamber 300, may form a portion of the case front surface 101.

Referring to FIG. 2A, the case upper surface 109 may be formed in a step manner, so that the case upper surface 109 may have a higher height at the rear than at the front. This may prevent the case 100 from falling forward towards the user due to the location of the module chamber.

The module hole 325 may be located on the case first side surface 102. Specifically, it may be desirable that the module hole 325 be located on the module first side surface 302. This is because discharging air before the flow of air past the charging or discharging module unit 500 weakens is effective in cooling the air outside the apparatus for charging or discharging 1000.

If all the air past the charging or discharging module unit 500 is discharged through the module hole 325, it will be difficult to maintain the temperature inside the case 100 or the temperature of the module chamber 300 within an acceptable range through the air treatment unit 340.

Therefore, the flow rate of air supplied to the module chamber 300 through the air treatment unit 340 will be greater than the flow rate of the air discharged through the module hole 325. In other words, a portion of the air past the air treatment unit 340 may be discharged through the module hole 325, but a portion may be redirected back to the inside of the case 100 and then returned to the air treatment unit 340.

Referring to FIG. 2A, the air treatment unit 340 may operate on the same principle as a general air conditioning device. In other words, the air treatment unit 340 may include a first heat exchanger (an evaporator) 341 (see FIG. 1) for heat exchange between surrounding air and refrigerant, a second heat exchanger (a condenser) 342, and a compressor 343 for compressing the refrigerant to circulate it. In addition, the air treatment unit 340 may further include an expansion unit (not shown) which expands the refrigerant passing through the condenser 342. In the present specification, unless otherwise specified, a heat exchanger refers to the first heat exchanger.

The condenser 342 may release heat to the surrounding air, and the compressor 343 may release heat when compressing the refrigerant, so they may be located outside the case 100. However, in this case, a separate space may be required for the condenser 342 and the compressor 343.

Accordingly, instead of positioning the condenser 342 inside the case 100, the disclosure may utilize water cooling for cooling by external water. To this end, the apparatus for charging or discharging 1000 may further include a circulation pipe 345 which is supplied with water from the outside for heat exchange with the condenser 342 and circulates the water.

The circulation pipe 345 may also be provided to exchange heat with the compressor 343.

In addition, the apparatus for charging or discharging 1000 may further include the controller 600 for controlling the charging or discharging module unit 500, the equipment temperature sensor 990, the air treatment unit 340, and the first input/output unit 210 and the second input/output unit 220.

As long as the control unit 600 can control the charging or discharging module unit 500, the equipment temperature sensor 990, the air treatment unit 340, the module fan 360, the first input/output unit 210, and the second input/output unit 220, the control unit 600 may be located anywhere inside the case 100.

In addition, the apparatus for charging or discharging 1000 may include a power supply unit (not shown) electrically connected to the outside to be supplied with power required for the apparatus for charging or discharging 1000.

Electric energy received through the power supply unit may also be used to charge and discharge the battery cells accommodated in the first chamber 161 and the second chamber 162 and to operate other necessary components, such as the controller 600 and the air treatment unit 340.

The form of electricity supplied to the power supply unit may be alternating current. Thus, the controller 600 may include an inverter 610 which converts the alternating current to direct current to obtain direct current required by the charging or discharging module unit 500 to charge the battery cell. In addition, the controller 600 may further include a DC-AC converter (an AC-DC converter) 690 which converts direct current to alternating current when discharging the battery cell. By utilizing the above converter, the electricity released during discharge may be regenerated without being discarded.

In addition, the controller 600 may further include a DC-DC converter (not shown) to convert electricity converted to direct current through the inverter 610 to direct current having predetermined voltage and current desired when charging the battery cell, e.g., 5 V (volts), 200 amperes.

Referring to FIG. 2B, the charging or discharging module unit 500 may include a plurality of charge-discharge channels 510. The plurality of charge-discharge channels 510 may be electrically connected to each jig and may charge or discharge the battery cells mounted on each of the jigs.

The charge-discharge channel 510 may include a current wiring (not shown) including a cable or a busbar for an electrical connection with the battery cell.

For example, the bus bar for electrically connecting the charge-discharge channel 510 and the jig corresponding to the charge-discharge channel 510 may be arranged at the shortest possible distance. This is to minimize loss due to heat generation when the length of the busbar increases.

For the apparatus for charging or discharging 1000 to charge the battery cell, the controller 600 may cause the AC type electricity to pass through the inverter and the DC-DC converter and charge the battery cell through the charge-discharge channel 510. When charging, the controller 600 may monitor the voltage of the battery cell which is being charged.

The apparatus for charging or discharging 1000 may include one integrated inverter 610 for the plurality of charge-discharge channels 510. Similarly, the apparatus for charging or discharging 1000 may include one DC-AC converter 690 for the plurality of charge-discharge channels 510.

The integrated inverter 610 and the integrated DC-AC converter 690 may minimize losses because they generate less heat than when a plurality of inverters and converters are provided. On the other hand, a plurality of the DC-DC converters may be provided depending on the number of charge-discharge channels 510, because charging or discharging conditions for the battery cells accommodated in respective chambers may be different.

For example, assuming that two battery cells are accommodated in the first chamber

161 and two battery cells are accommodated in the second chamber 162, the apparatus for charging or discharging 1000 may include two first jigs 410 inside the first chamber 161 and two second jigs 420 inside the second chamber 162. The apparatus for charging or discharging 1000 may require four charge-discharge channels 510 for four battery cells. One charge-discharge channel 510 may be connected one-to-one with one battery cell or one jig. However, this is merely one example described in the disclosure, and the number and arrangement method may be modified in various ways.

The charging or discharging module unit 500 may include one or more charging or discharging modules which are a collection of one or more charge-discharge channels 510. For example, referring to FIG. 2B, four charge-discharge channels may be stacked to form one charging or discharging module. Further, the charging or discharging module unit 500 may include one or more of the charging or discharging modules.

For example, referring to FIG. 2B, the apparatus for charging or discharging 1000 has four pairs of first chambers 161 and second chambers 162 stacked along the height direction of the case (100). Thus, if two battery cells are placed in each chamber, there are four charge-discharge channels 510 for a pair of the first chamber 161 and second chamber 162, and if the four charge-discharge channels 510 are regarded as one charge-discharge module, the charging or discharging module unit 500 may include four charging or discharging modules. However, this is merely one example described in the disclosure, and the number and arrangement method may be modified in various ways.

In addition, the first chamber 161 may include a first chamber first side surface 1612 located closer to the case first side surface 102 than the case second side surface 103 of two side surfaces of the first chamber 161 based on the width direction of the case 100, and a first chamber second side surface 1613 located closer to the case second side surface 103 than the case first side surface 102. In addition, the second chamber 162 may include a second chamber first side surface 1622 located closer to the case first side surface 102 than the case second side surface 103 of two side surfaces of the second chamber 162 based on the width direction of the case 100, and a second chamber second side surface 1623 located closer to the case second side surface 103 than the case first side surface 102.

To simplify the length of the bus bar provided between the charging or discharging module unit 500 and the first chamber 161 and the second chamber 162, an imaginary vertical line passing through the halfway point of the length (W2, see FIG. 1) of both ends of the charging or discharging module unit 500 along the width direction of the case 100 may coincide with an imaginary vertical line passing through the halfway point of the length (W3) of the first chamber first side surface 1612 and the second chamber second side surface 1623.

Referring to FIG. 2B, to cool the charging or discharging module unit 500, the first heat exchanger 341 which cools the air passing through the first heat exchanger may be located inside the module chamber 300. The first heat exchanger 341 may be located between the module fan 360 and the module second side surface 303. However, this is merely an example, and if air having a temperature lower than room temperature can be moved toward the charging or discharging module unit 500 through the module fan 360, the first heat exchanger 341 may be located elsewhere.

The controller 600 may discharge a portion of the air cooled by the air treatment unit 340 to the outside through the module hole 325 in case that the equipment temperature is higher than or equal to a preset allowable equipment temperature.

To this end, the apparatus for charging or discharging 1000 may further include the module cover 321 which opens or closes the module hole 325.

More specifically, the apparatus for charging or discharging 1000 may further include the module cover 321 which opens or closes the module hole 325, and an opening/closing driving unit 315 which opens or closes the module cover 321.

The controller 600 may operate the module cover 321 to open the module hole 325 and execute the air conditioning mode when the equipment temperature of the apparatus for charging or discharging 1000 reaches the allowable equipment temperature. Through this, at least a portion of the air past the charging or discharging module unit 500 may be discharged to the outside through the module hole 325, thereby lowering the outside temperature.

To prevent the apparatus for charging or discharging 1000 from being overloaded due to execution of the air conditioning mode, the controller 600 may not execute the air conditioning mode when usage current of the charging or discharging module unit 500 is greater than an allowable current. This is to prevent the battery cell currently being charged and discharged from being affected by unnecessarily executing the air conditioning mode because charging or discharging the battery cell accommodated in the accommodation chamber 161 or 162 through the charging or discharging module unit 500 already consumes a lot of power.

For measurement of the equipment temperature, the apparatus for charging or discharging 1000 further includes the equipment temperature sensor 990 which is located outside of the case and detects the equipment temperature of the case.

The controller 600 may determine the equipment temperature by the equipment temperature sensor 990. Through this, the controller 600 may selectively open the module hole 325 as needed to execute the air conditioning mode.

The module hole 325 may be located close to an upper portion of the charging or discharging module unit 500. This is because the charging or discharging module unit 500 interferes with the flow of air past the module fan 360. In other words, this is because the flow direction of air discharged from the air treatment unit 340 and passing through the charging or discharging module unit 500 may be changed to face an upper portion of the module chamber 300.

FIG. 3 is another example of the apparatus for charging or discharging 1000 according to the disclosure.

The apparatus for charging or discharging 1000 may include the case upper surface 109 forming the upper surface of the case 100 and the module upper surface 309 forming the upper surface of the module chamber 300 which is a part of the case upper surface 109. At least a part of the module upper surface 309 may be recessed in a direction away from the charging or discharging module unit 500 along the height direction of the case 100, thereby forming a module auxiliary chamber 390.

The module auxiliary chamber 390 may improve the flow of air moving along the module upper surface 309 toward the module hole 325 by increasing an empty space between the module upper surface 309 and the charging or discharging module unit 500.

Further, the module fan 360 may be provided to be inclined toward the upper portion of the module chamber 300 so that the flow of air moving toward the module hole 325 can move toward the module upper surface 309 and then move along the module upper surface 309.

In other words, the module fan 360 may be provided so that a rotation axis (not shown) of the module fan 360 is inclined toward the module upper surface 309.

In addition, the module hole 325 may be provided in one surface of the module auxiliary chamber 390. For example, the module fan 360 and the module hole 325 may be positioned in opposite directions with the charging or discharging module unit 500 interposed between the module fan 360 and the module hole 325.

Referring to FIG. 3, an example is shown in which the module hole 325 is provided in an auxiliary chamber front surface 391 which is a front surface of the module auxiliary chamber 390. Alternatively, the module hole 325 may be located in a side surface of the module auxiliary chamber 390 or may be located in an upper portion of one surface of the module chamber 300.

In FIG. 3, the flow of air inside the module chamber 300 is indicated by arrows. Considering the inclined direction of the module fan 360 and the position of the charging or discharging module unit 500, a portion of the air past the module fan 360 may pass through the module auxiliary chamber 390 and move toward the module hole 325. A portion of the air may be discharged to the outside through the module hole 325, and the rest may be blocked by side surfaces and move downward. In FIG. 3, the air passing through the module fan 360 is illustrated as circulating only inside the module chamber 300. Alternatively, the air passing through the module fan 360 may circulate inside the case 100.

Unlike FIG. 3, the apparatus for charging or discharging 1000 may be provided with the module upper surface 309 at an angle.

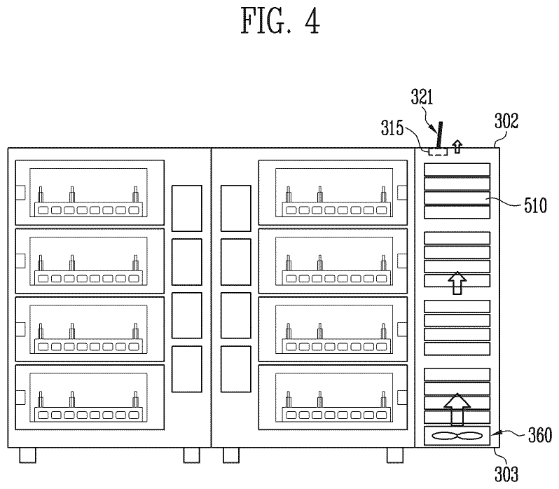

FIG. 4 shows an example in which the charging or discharging module unit 500 is provided along the height direction of the case 100.

Specifically, FIG. 4 shows an example in which the module chamber 300 is provided along the height direction of the case 100 rather than the width direction of the case 100.

FIG. 4 is an example in which the charging or discharging module unit 500 is provided along the height direction of the case 100. On the other hand, the charging or discharging module unit 500 may be located between the first chamber 161 and the second chamber 162 and be provided along the height direction of the case 100.

Referring to FIG. 4, the module chamber 300 or the charging or discharging module unit 500 may be located on any one side surface of two side surfaces of the case 100. One side surface of the module chamber 300 may form a portion of either the case first side surface 102 or the case second side surface 103.

Alternatively, the module chamber 300 or the charging or discharging module unit 500 may be separated and connected to an outer surface of the case.

Referring to FIG. 4, the module hole 325 and the module fan 360 may be located in opposite directions with the charging or discharging module unit 500 interposed between the module hole 325 and the module fan 360. Thus, in case that the module hole 325 is in a lower portion of the charging or discharging module unit 500, the module fan 360 may be in an upper portion of the charging or discharging module unit 500. However, in order to discharge the cooled air to the outside through the module hole 325, as shown in FIG. 4, it is preferable that the module hole 325 be located in an upper portion of the charging or discharging module unit 500, and the module fan 360 be located in a lower portion of the charging or discharging module unit 500.

Referring to FIG. 4, the plurality of charge-discharge channels 510 included in the charging or discharging module unit 500 may be stacked along the height direction of the case.

Assuming that the shape of the charge-discharge channel 510 is a hexahedron, the width of the charge-discharge channel may be greater than the height of the charge-discharge channel 510. Therefore, it may be advantageous for air flow using the module fan 360 to erect the charge-discharge channel by rotating it 90 degrees.

Since the charging or discharging module unit 500 is positioned toward one side of the case 100, the length of the busbar connecting the charge-discharge channel to the jig of each chamber may become longer and vary. This not only complicates the wiring of the busbar, but may also result in significant heat loss.

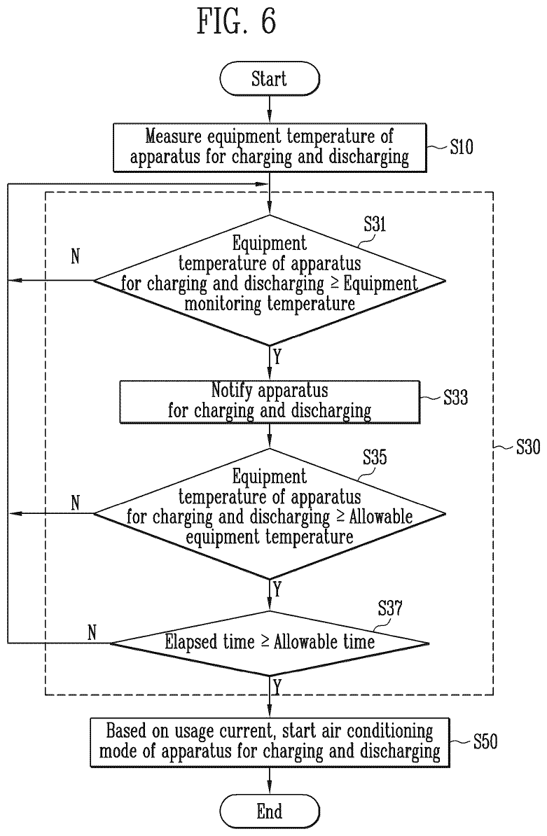

To solve this problem, referring to FIG. 6, the module chamber 300 may be located between the first chamber 161 and the second chamber 162.

A portion of the module chamber 300 may be located overlapping along the width direction of the case. In other words, the charging or discharging module unit 500 is positioned at the rear of the first chamber 161 and the second chamber 162, but when looking at the apparatus for charging or discharging from the front, it may be positioned between the first chamber 161 and the second chamber 162, specifically, between the first chamber first side surface 1612 (see FIG. 2B) and the second chamber second side surface 1623 (see FIG. 2B).

Due to the location of the module chamber 300, lengths from the charging or discharging module unit 500 to the first chamber 161 and to the second chamber 162 may be the same. Accordingly, the length of the bus bar (not shown) electrically connecting the charging or discharging module unit 500 to the first chamber 161 and the length of the busbar (not shown) electrically connecting the charging or discharging module unit 500 to the second chamber 162 may be the same.

Further, the plurality of charge-discharge channels 510 for charging or discharging the battery cells accommodated in the first chamber 161 and the second chamber 162 located at the same height may be grouped into one charging or discharging module and positioned between the heights of a lower surface and an upper surface of each of the first chamber 161 and the second chamber 162. This is to reduce heat loss and simplify busbar wiring by making the busbar as short as possible.

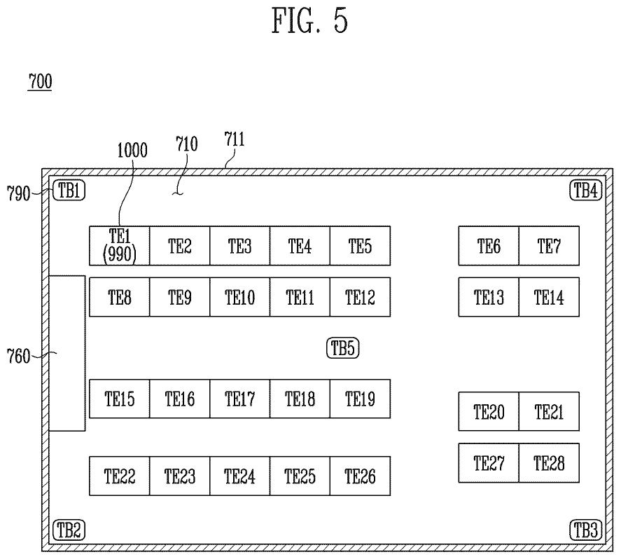

FIG. 5 shows an example of a battery charging or discharging system 700 according to the disclosure.

Referring to FIG. 5, the battery charging or discharging system 700 includes a plurality of the apparatuses for charging or discharging 1000 and a zone temperature sensor 790 which measures a zone temperature, which is a temperature of a zone 711 where the apparatus for charging or discharging 1000 is installed.

The apparatus for charging or discharging 1000 may be located at a selected position in a battery manufacturing process for charging or discharging of the battery cell. To this end, in the battery charging or discharging system 700 according to the disclosure, the zone 711 in which the apparatus for charging or discharging 1000 is installed includes a space 710 in which the apparatus for charging or discharging 1000 is installed and the zone temperature sensor 790 which measures the temperature of the zone 711.

The battery charging or discharging system 700 may be a part of the battery manufacturing process. Alternatively, the battery charging or discharging system 700 may be a part of a facility for researching the battery manufacturing process.

To this end, the battery charging or discharging system 700 may further include a system control device 760 which controls the zone temperature sensor 790 and the plurality of apparatuses for charging or discharging 1000. The system control device 760 may be electrically connected to the plurality of apparatuses for charging or discharging 1000 to exchange control signals with each other. The system control device 760 may be located in a separate space for controlling the battery charging or discharging system 700.

The zone temperature sensor 790 may be installed at a selected location in the zone 711 to measure the temperature of the zone 711. The system control device 760 may measure the temperature of the zone 711 in real time through the zone temperature sensor 790.

A plurality of the zone temperature sensors 790 may be provided, and the temperature of the zone 711 may be determined as an average value of the plurality of zone temperature sensors 790.

Alternatively, after the zone 711 is further subdivided, the zone temperature sensor 790 may be installed in each of the subdivided zones.

The zone 711 may be the entire space provided on one floor, or may be limited to a space where the plurality of apparatuses for charging or discharging 1000 are installed.

FIG. 5 shows an example in which the plurality of apparatuses for charging or discharging 1000 are arranged in two rows or in a row in the zone 711. Since each of the plurality of apparatuses for charging or discharging 1000 includes the equipment temperature sensor 990, the system control device 760 may be able to identify the equipment temperature around where each of the plurality of apparatuses for charging or discharging 1000 is located through each of equipment temperature sensors (TE1 to TE22).

Further, referring to FIG. 5, the system control device 760 may be able to identify the temperature of the zone where the plurality of apparatuses for charging or discharging 1000 are located through five zone temperature sensors (TB1 to TB5) installed in the zone 711. However, this is merely an example, and the number of installed plurality of apparatuses for charging or discharging and the number of zone temperature sensors 790 may vary depending on the situation.

FIG. 6 shows a flowchart illustrating an example of a control method of the apparatus for charging or discharging 1000 according to the disclosure.

More specifically, FIG. 6 shows an example of a control method in which the air conditioning mode is executed in the apparatus for charging or discharging 1000. As described above, the air conditioning mode is provided to cool the charging or discharging module unit 500 and refers to a mode in which a portion of the air discharged from the air treatment unit 340 which supplies cooled air toward the charging or discharging module unit 500 is discharged to the outside to lower the equipment temperature, which is the temperature around the apparatus for charging or discharging 1000. In other words, the air conditioning mode means a mode to control the equipment temperature using the apparatus for charging or discharging 1000.

However, to prevent the apparatus for charging or discharging 1000 from being overloaded due to the execution of the air conditioning mode, the air conditioning mode may be executed only when the apparatus for charging or discharging 1000 satisfies predetermined conditions.

For example, since the apparatus for charging or discharging 1000 in a high-power state is already charging or discharging the accommodated battery cell through the charging or discharging module unit 500, there is no need to forcefully lower the equipment temperature. On the other hand, the apparatus for charging or discharging 1000 in a low-power state or in a standby state may be able to perform the air conditioning mode to lower the equipment temperature.

To this end, based on the usage current of the charging or discharging module unit 500 and the equipment temperature, the controller 600 may perform the air conditioning mode in which at least a portion of the air discharged from the air treatment unit 340 is discharged to the outside of the case 100 through the module hole 325 by opening the module cover 321.

To this end, when the air treatment unit 340 including the module fan 360, the first heat exchanger 341, and the second heat exchanger 342 operates, the controller 600 may open the module hole 325 through the module cover 321 to perform the air conditioning mode.

More specifically, a control method of the apparatus for charging or discharging 1000 according to the disclosure may include measuring the equipment temperature of the apparatus for charging or discharging 1000 (S10), determining whether the air conditioning mode of the apparatus for charging or discharging 1000 is necessary (S30), and starting the air conditioning mode of the apparatus for charging or discharging 1000 based on the usage current of the charging or discharging module unit 500 (S50).

In the step of measuring the equipment temperature of the apparatus for charging or discharging 1000 (S10), the controller 600 may measure the temperature of the outside of the place where the apparatus for charging or discharging 1000 is located using the equipment temperature sensor 990.

The step of determining whether the air conditioning mode of the apparatus for charging or discharging 1000 is necessary (S30) may include comparing the equipment temperature of the apparatus for charging or discharging 1000 with a preset allowable equipment temperature (S35).

Preferably, the allowable equipment temperature may be set to a set zone temperature +5° C. (degree Celsius). In case that the zone temperature is set to 25° C., the allowable equipment temperature may be 30° C.

After the step of determining whether the air conditioning mode of the apparatus for charging or discharging 1000 is necessary (S30), the control method of the apparatus for charging or discharging 1000 according to the disclosure may perform starting the air conditioning mode of the apparatus for charging or discharging 1000 based on the usage current of the charging or discharging module unit 500 (S50). Even if the equipment temperature is higher than or equal to the allowable equipment temperature, in order to perform the air conditioning mode in the apparatus for charging or discharging 1000, the usage current of the charging or discharging module unit 500 is determined so as not to affect the battery cell currently being charged or discharged.

In other words, if the usage current of the charging or discharging module unit 500 is greater than or equal to a preset allowable current, the controller 600 may not execute the air conditioning mode of the apparatus for charging or discharging 1000. If the usage current of the charging or discharging module unit 500 is less than the preset allowable current, the controller 600 may execute the air conditioning mode of the apparatus for charging or discharging 1000.

For example, the allowable current may be set to 900 A (amperes) for 16 channels.

For example, when the usage current of the charging or discharging module unit 500 is greater than or equal to the allowable current, the controller 600 may maintain the module hole 325 closed through the module cover 321.

Further, in case that the usage current of the charging or discharging module unit 500 is less than the allowable current and the equipment temperature is less than the preset allowable equipment temperature, the controller 600 may maintain the module hole 325 closed through the module cover 321.

The step of determining whether the air conditioning mode of the apparatus for charging or discharging 1000 is necessary (S30) may further include determining whether a time period during which the equipment temperature of the apparatus for charging or discharging 1000 has reached the allowable equipment temperature and is continuously maintained above the allowable equipment temperature reaches a preset allowable time (S37). This is because, even if the equipment temperature exceeds the allowable equipment temperature, there is no need to start the air conditioning mode of the apparatus for charging or discharging 1000 if the equipment temperature immediately drops below the allowable equipment temperature.

Preferably, the allowable time may be three (3) hours.

For example, when the usage current of the charging or discharging module unit 500 is less than the preset allowable current and the time period during which the equipment temperature has reached the preset allowable equipment temperature and is continuously maintained above the allowable equipment temperature reaches the allowable time, the controller 600 may discharge at least a portion of the air discharged from the air treatment unit 340 to the outside of the case 100 through the module hole 325.

Also, when the usage current of the charging or discharging module unit 500 is less than the preset allowable current and the time period during which the equipment temperature is continuously maintained above the allowable equipment temperature after reaching the allowable equipment temperature is shorter than the allowable time, the controller 600 may maintain the module hole 325 closed through the module cover 321.

On the other hand, when the usage current of the charging or discharging module unit 500 is greater than or equal to the allowable current, the controller 600 may maintain the module hole 325 closed through the module cover 321. In other words, regardless of the elapsed time, the controller 600 will not perform the air conditioning mode by closing the module hole 325 through the module cover 321.

Further, in case that the usage current of the charging or discharging module unit 500 is less than the allowable current and the equipment temperature is less than the allowable equipment temperature, the controller 600 may maintain the module hole 325 closed through the module cover 321. In other words, because the apparatus for charging or discharging 1000 is operating within the allowable equipment temperature, the controller 600 does not need to perform the air conditioning mode.

To warn or notify the user prior to the step of comparing the equipment temperature of the apparatus for charging or discharging 1000 with the preset allowable equipment temperature (S35), the step of determining whether the air conditioning mode of the apparatus for charging or discharging 1000 is necessary (S30) may further include determining whether the equipment temperature of the apparatus for charging or discharging 1000 reaches a preset equipment monitoring temperature (S31) and notifying the apparatus for charging or discharging when the equipment temperature reaches the equipment monitoring temperature (S33).

The equipment monitoring temperature may be lower than the allowable equipment temperature. Therefore, before reaching the allowable equipment temperature, it is possible to notify the user in advance that the apparatus for charging or discharging 1000 requires attention. The controller 600 may notify the user of the status of the apparatus for charging or discharging 1000 through a terminal or portable terminal managed by the user.

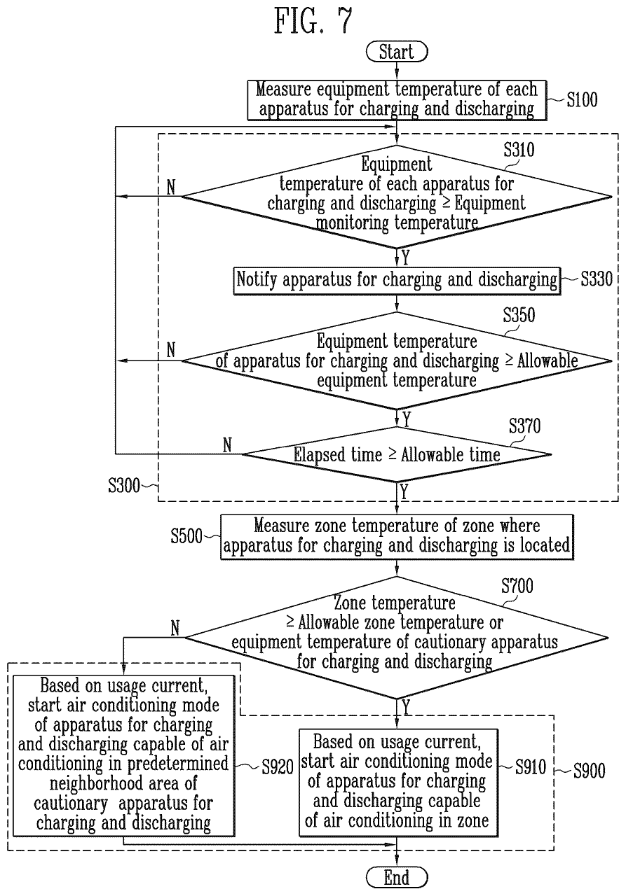

FIG. 7 is a flowchart illustrating an example of a control method of the battery charging or discharging system 700 according to the disclosure.

FIG. 6 relates to the control method of the apparatus for charging or discharging 1000 which executes the air conditioning mode in one apparatus for charging or discharging 1000. On the other hand, FIG. 7 relates to a control method of the battery charging or discharging system 700 which performs the air conditioning mode of the plurality of apparatuses for charging or discharging 1000 based on the zone temperature which is the temperature of the zone 711 in which the plurality of apparatuses for charging or discharging 1000 are accommodated and each equipment temperature in the plurality of apparatuses for charging or discharging 1000.

The control method of the battery charging or discharging system 700 according to the disclosure may include measuring, through the equipment temperature sensor 990 which is provided in the case 100 of each of the plurality of apparatuses for charging or discharging 1000 and measures the equipment temperature which is the external temperature of each apparatus for charging or discharging 1000, the equipment temperature of the apparatus for charging or discharging 1000 (S100), selecting a cautionary apparatus for charging or discharging which requires temperature control among the plurality of apparatuses for charging or discharging 1000 based on the equipment temperature of each of the plurality of apparatuses for charging or discharging 1000 (S300), measuring the zone temperature through the zone temperature sensor 790 (S500), and starting the air conditioning mode for discharging at least a portion of the air discharged from the air treatment unit 340 of each of at least some apparatuses for charging or discharging 1000 out of the plurality of apparatuses for charging or discharging 1000 to the outside and selecting an air conditioning range based on the zone temperature, the equipment temperature of the cautionary apparatus for charging or discharging, and the usage current of respective charging or discharging module units 500 of the plurality of apparatuses for charging or discharging 1000 (S700, S900).

In the step of measuring, through the equipment temperature sensor 990 which is provided in the case 100 of each of the plurality of apparatuses for charging or discharging 1000 and measures the equipment temperature which is the external temperature of the apparatus for charging or discharging 1000, the equipment temperature of the apparatus for charging or discharging 1000 (S100), the control method of the battery charging or discharging system 700 according to the disclosure may measure the equipment temperature through the plurality of apparatuses for charging or discharging 1000. Even if the plurality of apparatuses for charging or discharging 1000 have the same usage current of the charging or discharging module units 500, the plurality of apparatuses for charging or discharging 1000 may have different equipment temperatures, which are external temperatures of the plurality of apparatuses for charging or discharging 1000, depending on whether they are in operation.

Thereafter, the control method of the battery charging or discharging system 700 according to the disclosure may perform a step of selecting an apparatus for charging or discharging requiring the temperature control among the plurality of apparatuses for charging or discharging 1000 based on the respective equipment temperatures of the plurality of apparatuses for charging or discharging 1000 (S300).

In other words, the control method of the battery charging or discharging system 700 according to the disclosure may select, among the plurality of apparatuses for charging or discharging 1000, a cautionary apparatus for charging or discharging which reaches the allowable time at or above the allowable equipment temperature and requires attention. In other words, based on the allowable equipment temperature and the allowable time described above with respect to FIG. 6, the control method of the battery charging or discharging system 700 according to the disclosure may select the cautionary apparatus for charging or discharging among the plurality of apparatuses for charging or discharging 1000.

Based on the respective equipment temperatures of the plurality of apparatuses for charging or discharging, the selecting of the cautionary apparatus for charging or discharging which requires the temperature control among the plurality of apparatuses for charging or discharging 1000 (S300) may include determining whether the respective equipment temperatures of the plurality of apparatuses for charging or discharging 1000 are higher than or equal to the preset allowable equipment temperature (S350).

Preferably, the allowable equipment temperature may be set to the set zone temperature +5° C. (degree Celsius). If the zone temperature is set to 25° C., the allowable equipment temperature may be 30° C.

Further, the selecting of the cautionary apparatus for charging or discharging requiring the temperature control among the plurality of apparatuses for charging or discharging 1000 based on the respective equipment temperatures of the plurality of apparatuses for charging or discharging (S300) may further include determining whether the time period during which the equipment temperature of each of the plurality of apparatuses for charging or discharging 1000 has reached the allowable equipment temperature and is continuously maintained above the allowable equipment temperature reaches a preset allowable time (S370). This is because, even if the equipment temperature exceeds the allowable equipment temperature, there is no need to start the air conditioning mode of the apparatus for charging or discharging 1000 if the equipment temperature immediately drops below the allowable equipment temperature.

Preferably, the allowable time may be three (3) hours.

Among the plurality of apparatuses for charging or discharging 1000, an apparatus which has the equipment temperature is below the allowable equipment temperature or is shorter than the allowable time repeatedly performs measuring of the equipment temperature through the equipment temperature sensor.

To warn or notify the user prior to the step of determining whether the respective equipment temperatures of the plurality of apparatuses for charging or discharging 1000 are higher than or equal to the preset allowable equipment temperature (S350), the selecting of the cautionary apparatus for charging or discharging requiring the temperature control among the plurality of apparatuses for charging or discharging 1000 (S300) may further include determining whether the equipment temperature of each of the plurality of apparatuses for charging or discharging 1000 reaches the preset equipment monitoring temperature (S310) and notifying an apparatus for charging or discharging which reaches the equipment monitoring temperature among the plurality of apparatuses for charging or discharging (S330).

The equipment monitoring temperature may be lower than the allowable equipment temperature. Therefore, before reaching the allowable equipment temperature, it is possible to notify the user in advance of the cautionary apparatus for charging or discharging which requires attention among the plurality of apparatuses for charging or discharging 1000. The controller 600 may notify the user of the status of the cautionary apparatus for charging or discharging through a terminal or a portable terminal managed by the user.

After the step of selecting the cautionary apparatus for charging or discharging which requires the temperature control among the plurality of apparatuses for charging or discharging 1000 (S300), the control method of the battery charging or discharging system 700 according to the disclosure may perform the step of measuring the zone temperature through the zone temperature sensor 790 of the zone 711 where the plurality of apparatuses for charging or discharging are located (S500).

Based on the zone temperature, the control method of the battery charging or discharging system 700 according to the disclosure may determine whether to operate all of the apparatuses for charging or discharging 1000 capable of air conditioning among the plurality of apparatuses for charging or discharging 1000, or to operate only the apparatus for charging or discharging 1000 capable of air conditioning among the apparatuses for charging or discharging 1000 located in a predetermined neighborhood area around the cautionary apparatus for charging or discharging.

To this end, after the step of measuring the zone temperature through the zone temperature sensor (S500), the control method of the battery charging or discharging system 700 according to the disclosure may perform a step of selecting the air conditioning range by comparing the zone temperature with a preset allowable zone temperature or comparing the zone temperature with the equipment temperature of the cautionary apparatus for charging or discharging (S700).

For example, if the zone temperature is higher than or equal to the allowable zone temperature, the control method of the battery charging or discharging system 700 according to the disclosure may utilize the air conditioning mode of the plurality of apparatuses for charging or discharging 1000 located within the zone because it is necessary to manage the temperature of the entire zone.

On the other hand, if the zone temperature is less than the allowable zone temperature, the control method of the battery charging or discharging system 700 according to the disclosure may determine that it is necessary to manage only the equipment temperature of the cautionary apparatus for charging or discharging, and thus utilize the air conditioning mode of the apparatus for charging or discharging 1000 located in the neighborhood area of the cautionary apparatus for charging or discharging.

In other words, through the comparison of the zone temperature and the allowable zone temperature, the control method of the battery charging or discharging system 700 according to the disclosure may select the air conditioning range.

As another example, if the zone temperature is higher than or equal to the equipment temperature of the cautionary apparatus for charging or discharging, the control method of the battery charging or discharging system 700 according to the disclosure may utilize the air conditioning mode of the plurality of apparatuses for charging or discharging 1000 located within the zone 711 because it is necessary to manage the temperature of the entire zone.

On the other hand, if the zone temperature is less than the equipment temperature of the cautionary apparatus for charging or discharging, the control method of the battery charging or discharging system 700 according to the disclosure may determine that it is necessary to manage only the equipment temperature of the cautionary apparatus for charging or discharging, and thus utilize the air conditioning mode of the apparatus for charging or discharging 1000 located in the neighborhood area based on the cautionary apparatus for charging or discharging.

In other words, through the comparison of the zone temperature and the equipment temperature of the cautionary apparatus for charging or discharging, the control method of the battery charging or discharging system 700 according to the disclosure may select the air conditioning range.

Thereafter, the control method of the battery charging or discharging system 700 according to the disclosure may perform a step of starting the air conditioning mode of the apparatus for charging or discharging 1000 which can be utilized in the air conditioning mode based on the usage current of each charging or discharging module unit 500 (S900).

In other words, even if the air conditioning mode is required, the air conditioning mode cannot be started in the apparatus for charging or discharging in which the usage current of the charging or discharging module unit 500 is greater than or equal to the preset allowable current, so the control method of the battery charging or discharging system 700 according to the disclosure may compare the usage current of each charging or discharging module unit 500 with the allowable current to determine whether the apparatus for charging or discharging 1000 is capable of air conditioning.

For example, if the zone temperature is higher than or equal to the allowable zone temperature or the zone temperature is higher than or equal to the equipment temperature of the cautionary apparatus for charging or discharging, the control method of the battery charging or discharging system 700 according to the disclosure may perform the step of starting the air conditioning mode of the apparatus for charging or discharging 1000 capable of air conditioning in which the usage current of the charging or discharging module unit 500 is less than the allowable current among the plurality of apparatuses for charging or discharging 1000 (S910).

In other words, in the step of selecting the air conditioning range (S700), the control method of the battery charging or discharging system 700 according to the disclosure may select the air conditioning range as the entire zone and start the air conditioning mode of all apparatuses for charging or discharging 1000 capable of air conditioning 1000 within the zone.

On the other hand, if the zone temperature is lower than the allowable zone temperature or the zone temperature is lower than the equipment temperature of the cautionary apparatus for charging or discharging, the control method of the battery charging or discharging system 700 according to the disclosure may perform a step of starting the air conditioning mode of the apparatus for charging or discharging 1000 located in the neighborhood area based on the cautionary apparatus for charging or discharging (S920).
when the zone temperature is lower than the equipment temperature of the cautionary apparatus for charging or discharging, the air conditioning mode can be started in an apparatus for charging or discharging in which the usage current of the charging or discharging module unit is less than the allowable current among apparatuses for charging or discharging located in a predetermined neighborhood area of the cautionary apparatus for charging or discharging. Also, When the zone temperature is lower than the allowable zone temperature, the air conditioning mode can be started in an apparatus for charging or discharging in which the usage current of the charging or discharging module unit is less than the allowable current among apparatuses for charging or discharging located in a predetermined neighborhood area of the cautionary apparatus for charging or discharging.

In other words, in the step of selecting the air conditioning range (S700), the control method of the battery charging or discharging system 700 according to the disclosure may select the air conditioning range within the neighborhood area and start the air conditioning mode of the apparatus for charging or discharging 1000 capable of air conditioning within the neighborhood area.

In addition, since the cautionary apparatus for charging or discharging has already exceeded the allowable time and the allowable equipment temperature, the equipment temperature of the cautionary apparatus for charging or discharging may be lowered by utilizing the apparatus for charging or discharging 1000 capable of air conditioning among adjacent apparatuses for charging or discharging 1000 within the neighborhood area, rather than the air treatment unit 340 of the cautionary apparatus for charging or discharging.

This is because the cautionary apparatus for charging or discharging is not the apparatus for charging or discharging capable of air conditioning (1000) whether the entire zone is air-conditioned or only the neighborhood area is air-conditioned.

In case that the usage current of the charging or discharging module unit 500 is greater than or equal to the allowable current, the controller 600 may maintain the module hole 325 closed through the module cover 321.

In case that the usage current of the charging or discharging module unit 500 is less than the preset allowable current, the controller 600 may execute the air conditioning mode of the apparatus for charging or discharging 1000. For example, the allowable current may be set to 900 A (amperes) for 16 channels.

The disclosure may be embodied in various forms and the scope is not limited to the above-described embodiments. Accordingly, if a modified embodiment includes a component of the appended claims of the disclosure, it should be considered to fall within the scope of the disclosure.

What is claimed is:

1. An apparatus for charging or discharging, comprising:
a case comprising a receiving port in a front surface;
a receiving chamber located inside the case and receiving at least one battery cell through the receiving port;
a charging or discharging module unit configured to charge and discharge the at least one battery cell accommodated in the receiving chamber inside the case;
an air treatment unit provided inside the case and configured to discharge air toward the charging or discharging module unit to cool the charging or discharging module unit;
an equipment temperature sensor located in the case and sensing an equipment temperature, which is a temperature outside the case;
a module hole formed by penetrating the case and communicating with an outside;
a module cover which opens or closes the module hole; and
a controller configured to control the charging or discharging module unit, the air treatment unit, and the equipment temperature sensor,
wherein the controller is configured to open the module cover to discharge at least a portion of the air discharged from the air treatment unit to the outside of the case through the module hole based on usage current of the charging or discharging module unit and the equipment temperature.

2. The apparatus according to claim 1, wherein the controller is configured to open the module cover to discharge at least a portion of the air discharged from the air treatment unit to the outside of the case through the module hole, when the usage current of the charging or discharging module unit is less than a preset allowable current and the equipment temperature reaches a preset allowable equipment temperature.

3. The apparatus according to claim 2, wherein the controller is configured to maintain the module hole closed through the module cover, when the usage current of the charging or discharging module unit is greater than or equal to the allowable current.

4. The apparatus according to claim 2, wherein the controller is configured to maintain the module hole closed through the module cover, when the usage current of the charging or discharging module unit is less than the allowable current and the equipment temperature is less than the preset allowable equipment temperature.

5. The apparatus according to claim 2, wherein the controller is configured to discharge at least a portion of the air discharged from the air treatment unit to the outside of the case through the module hole, when the usage current of the charging or discharging module unit is less than the preset allowable current, and a time period during which the equipment temperature has reached the preset allowable equipment temperature and is continuously maintained above the allowable equipment temperature reaches a preset allowable time.

6. The apparatus according to claim 5, wherein the controller is configured to maintain the module hole closed through the module cover, when the usage current of the charging or discharging module unit is greater than or equal to the allowable current.

7. The apparatus according to claim 5, wherein the controller is configured to maintain the module hole closed through the module cover, when the usage current of the charging or discharging module unit is less than the allowable current and the equipment temperature is less than the allowable equipment temperature.

8. The apparatus according to claim 5, wherein the controller is configured to maintain the module hole closed through the module cover, when the usage current of the charging or discharging module unit is less than the allowable current and a time period during which the equipment temperature is continuously maintained above the allowable equipment temperature after reaching the allowable equipment temperature is shorter than the allowable time.

9. A method of controlling a battery charging or discharging system which comprises a plurality of apparatuses for charging or discharging each comprising a case comprising a receiving port in a front surface; a receiving chamber located inside the case and receiving at least one battery cell through the receiving port; a charging or discharging module unit configured to charge and discharge the at least one battery cell accommodated in the receiving chamber inside the case; and an air treatment unit which is provided inside the case and configured to discharge air toward the charging or discharging module unit to cool the charging or discharging module unit; and a zone temperature sensor measuring a zone temperature which is a temperature of a zone in which the plurality of apparatuses for charging or discharging are installed, the method comprising:
measuring an equipment temperature of each of the plurality of apparatuses for charging or discharging through an equipment temperature sensor which is provided in the case of the apparatus for charging or discharging and measures the equipment temperature of the apparatus for charging or discharging;
selecting a cautionary apparatus for charging or discharging requiring temperature control among the plurality of apparatuses for charging or discharging based on the equipment temperature of each of the plurality of apparatuses for charging or discharging;
measuring the zone temperature through the zone temperature sensor; and
selecting an air conditioning range and starting an air conditioning mode to discharge at least a portion of the air discharged from respective air treatment units of at least one or more apparatuses for charging or discharging among the plurality of apparatuses for charging or discharging to an outside based on the zone temperature, the equipment temperature of the cautionary apparatus for charging or discharging, and usage current of respective charging or discharging module units of the plurality of apparatuses for charging or discharging.

10. The method according to claim 9, wherein the selecting of the cautionary apparatus for charging or discharging requiring the temperature control among the plurality of apparatuses for charging or discharging based on the equipment temperature of each of the plurality of apparatuses for charging or discharging comprises:
determining whether the equipment temperature of each of the plurality of apparatuses for charging or discharging is higher than or equal to a preset allowable equipment temperature; and
determining whether a time period during which the equipment temperature has reached the allowable equipment temperature and is continuously maintained above the allowable equipment temperature reaches a preset allowable time, and
wherein, among the plurality of apparatuses for charging or discharging, an apparatus for charging or discharging which has the equipment temperature higher than or equal to the allowable equipment temperature and reaches the allowable time is selected as the cautionary apparatus for charging or discharging.

11. The method according to claim 10, wherein, among the plurality of apparatuses for charging or discharging, an apparatus for charging or discharging which has the equipment temperature is below the allowable equipment temperature or is shorter than the allowable time repeatedly performs measuring of the equipment temperature through the equipment temperature sensor.

12. The method according to claim 10, wherein the selecting of the air conditioning range and starting of the air conditioning mode comprises starting the air conditioning mode in an apparatus for charging or discharging capable of air conditioning in which the usage current of the charging or discharging module unit is less than a preset allowable current among the plurality of apparatuses for charging or discharging when the zone temperature is higher than or equal to the equipment temperature of the cautionary apparatus for charging or discharging.

13. The method according to claim 12, wherein the selecting of the air conditioning range and starting of the air conditioning mode comprises starting the air conditioning mode in an apparatus for charging or discharging capable of air conditioning in which the usage current of the charging or discharging module unit is less than the allowable current among apparatuses for charging or discharging located in a predetermined neighborhood area of the cautionary apparatus for charging or discharging when the zone temperature is lower than the equipment temperature of the cautionary apparatus for charging or discharging.

14. The method according to claim 10, wherein the selecting of the air conditioning range and starting of the air conditioning mode comprises starting the air conditioning mode in an apparatus for charging or discharging capable of air conditioning in which the usage current of the charging or discharging module is less than a preset allowable current among the plurality of apparatuses for charging or discharging when the zone temperature is higher than or equal to a preset allowable zone temperature.

15. The method according to claim 13, wherein the selecting of the air conditioning range and starting of the air conditioning mode comprises starting the air conditioning mode in an apparatus for charging or discharging capable of air conditioning in which the usage current of the charging or discharging module unit is lower than the allowable current among apparatuses for charging or discharging located in the neighborhood area of the cautionary apparatus for charging or discharging, when the zone temperature is lower than an allowable zone temperature.

16. The method according to claim 10, wherein the selecting of the cautionary apparatus for charging or discharging requiring the temperature control among the plurality of apparatuses for charging or discharging based on the equipment temperature of each of the plurality of apparatuses for charging or discharging comprises:
prior to determining whether the equipment temperature of each of the plurality of apparatuses for charging or discharging is higher than or equal to the preset allowable equipment temperature, determining whether the equipment temperature reaches a preset equipment monitoring temperature; and
notifying a user of an apparatus for charging or discharging which reaches the equipment monitoring temperature among the plurality of apparatuses for charging or discharging.
